(19) United States
(12) Patent Application Publication
(10) Pub. No.: US 2026/0316118 A1
(43) Pub. Date: Oct. 15, 2026

(54) DEVICE FOR REMOVING WIRES FROM A WIRE BUNDLE

(71) Applicant: IDEAL - Werk C. + E. Jungeblodt GmbH + Co. KG, Lippstadt (DE)

(72) Inventor: Reinhold Hils, Delbrück (DE)

(21) Appl. No.: 19/643,107

(22) Filed: Apr. 9, 2026

(30) Foreign Application Priority Data
Apr. 9, 2025 (EP) 25169546.6

(51) Int. Cl. B07B 13/16; B21F 23/00

(52) U.S. Cl. CPC B07B 13/16; B21F 23/005

(57) ABSTRACT

A device for removing wires from a wire bundle comprises: a shelf to support the wire bundle; a guide to align the wires removed from the wire bundle; a rotatably mounted removal wheel to remove a wire from the wire bundle and to transfer the wire to the guide, the removal wheel comprising a notch for entraining the wire and into which the wire is entrapped during rotation of the removal wheel; a drive to drive rotation of the removal wheel; rotatable transport wheels arranged coaxially with the removal wheel, each of the transport wheels comprising a notch for entraining the wire that is entrapped in the entrainment notch of the removal wheel; and prevention elements to block the wires from the wire bundle that are not entrapped in the notch of the removal wheel from being entrapped in notches of the transport wheels.

### CROSS REFERENCE TO RELATED APPLICATIONS

This application claims priority under 35 U.S.C. § 119(a)-(d) to European application No. 25169546.6, filed on Apr. 9, 2025, the entire contents of which are hereby incorporated by reference.

### TECHNICAL FIELD

The present disclosure relates to a device for the removal of wires from a wire bundle and for the alignment of the wires, comprising a shelf for the wire bundle, a guide for the alignment of the wires removed from the wire bundle, a rotatably mounted removal wheel for removing one wire from the wire bundle and for transferring the removed wire to the guide, and a drive for driving the rotation of the removal wheel, wherein the removal wheel comprises a notch for entraining a wire, into which a wire of the wire bundle is entrapped during rotation of the removal wheel and by which this wire is entrained.

### BACKGROUND

For the manufacture of wire mesh, wires must be sorted, separated, and fed into a welding machine, some as longitudinal wires and others as transverse wires. The wires are delivered in bundles. The wires must be removed from these wire bundles and separated before they can be processed in the welding machine.

The removal of a single wire from a disordered and loose wire bundle is also referred to as sorting. After removal of a wire from the wire bundle, it is fed into a space between two guide elements, such that an ordered, aligned arrangement of wires that allows for separation is achieved. This sorting process often leads to errors, particularly with very long and thin wires that are frequently intertwined within the wire bundle.

In addition to other sorting approaches, the use of a sorting or removal wheel is common. This removal wheel is typically positioned centrally relative to the wire length and removes a wire from the wire bundle via an entrainment notch. A circular motion of the wire center grasped by the entrainment notch follows, which wire center initially has a strong vertical component. The wire ends of the wire entrained by the removal wheel may initially lie between the other wires of the wire bundle. These may lie beneath other wires of the bundle, so that they are not lying freely. Only as the height of the center of the wire to be removed increases does the vertical movement continue toward the wire ends. More and more of the entrained wire is drawn along by the entrainment notch of the removal wheel. In so doing, the entrained wire is subjected to bending.

By entraining the wire with the help of the removal wheel only in the middle of the wire, a bending stress in the wire cannot be avoided. The force, required to remove the entrained wire from the wire coil, generates a downward force component that creates a torque in the wire. An increasing wire length and a decreasing wire diameter ultimately affect the stress conditions in the wire, so that plastic deformation of the wire can occur, in particular in the case of long and/or thin wires.

To reduce the problem of plastic deformation, the lever arm of the force acting on the wire in the entrainment notch must be significantly reduced. From the perspective of bending, the most favorable solution would support the upward movement along the entire length of the wire entrained by the removal wheel.

This could be achieved by an increase of the number of removal wheels. A use of two or more removal wheels is not readily possible, as there is no guarantee that the removal wheels will remove the same wire from the wire bundle. There is no guarantee that the same wire will be selected for entrainment by the entrainment notches of the removal wheels.

### SUMMARY

The disclosed device is therefore based on the unsolved problem of reducing the force applied to the wire to be removed from the wire bundle in order to reduce or, in the best case, even prevent plastic deformation of the wire.

According to the disclosure, this problem is solved in that: a) the device comprises transport wheels that are arranged coaxially and at a distance from the removal wheel, each of which comprises a notch for entraining the wire that is entrapped in the entrainment notch of the removal wheel, and b) in that the device comprises prevention elements used to block a wire from being entrapped in the entrainment notches of the transport wheels, by which it is prevented that a wire, of the wire bundle, is entrapped in the entrainment notch that is not entrapped in the entrainment notch of the removal wheel.

To remove a wire from a wire bundle and to align the removed wire using a device, the following procedure may be followed: using an entrainment notch of the rotating removal wheel, a wire from the wire bundle is grasped, and the grasped portion of the wire is entrained by the removal wheel and removed from the wire bundle. In so doing, the removed wire is moved by the contact surface or contact edge of the prevention elements used to block a wire from being entrapped by the entrainment notches of the transport wheels, all the way to their upper ends. Once the upper end is reached, the removed wire is then grasped by the entrainment notches of the transport wheels and transported to the guide. At the beginning, the removed wire is extricated from the entrainment notches of the removal wheel and the transport wheels and moved into the guide.

A large number of transport wheels is necessary along the entire length of the wire to achieve short distances between the resistance to the wires being extricated from the wire coil and the upward force of the removal wheel. The removal wheel with the entrainment notch serves to select the wire that is to be extricated next from the wire coil. The upward movement of the section of the wire grasped by the entrainment notch of the removal wheel continues to extend into other areas of the wire, which are lifted. The sections of the entrained wire lifted in this manner can be used for further identification of the wire, in order to support the correct wire in its further upward movement through the transport wheels. These additional supports for the wire therefore only take effect at a height where only the wire entrained by the sorting wheel can be located. This is achieved by the prevention elements used to block a wire from being entrapped in the entrainment notches of the transport wheels, which prevent any wire that has not been extricated by the removal wheel from being entrapped.

A distinctive feature of the disclosed device is the provision of an element in front of the lower areas of each respective transport wheel to prevent the transport wheels from entraining a wire that has not been extricated from the wire coil by the removal wheel. Only the wire lifted by the removal wheel can be grasped and entrained by the transport wheels.

Preferably, the removal wheel is arranged in the center of the transport wheels so that the center of the wire to be entrained can be grasped by the removal wheel. In principle, however, the removal wheel may also be provided at one end of the transport wheels arranged side by side.

Preferably, the transport wheels can be driven by the same drive as the removal wheel.

It is possible for a gearbox to be arranged between the drive and the removal wheel and/or between the drive and one or more or all of the transport wheels, so that the wheels can be driven by the same drive but at different speeds.

A particularly simple transmission of rotational motion from the drive to the removal wheel and the transport wheels is possible if the removal wheel and the transport wheels are arranged rotationally fixed on a shaft. This shaft can then be directly coupled to a shaft of the drive.

It has been found to be advantageous if the transport wheels comprise a greater number of entrainment notches than the removal wheel.

Preferably, at least one of the prevention elements used to block a wire from being entrapped in the entrainment notches of the transport wheels is associated with each of the transport wheels.

The prevention elements of a removal and alignment device according to the disclosed device may extend: a) when viewed from a rotational axis of the transport wheels in the direction of the shelf beyond the transport wheels, and b) when viewed from the shelf over a shelf plane defined beyond the shelf for the wire bundle.

The prevention elements may have a circularly curved contact surface or contact edge, wherein the contact surface or contact edge of each element lies on a circle about the axis of rotation of the transport wheel to which the element is assigned.

An angle between the shelf plane and an upper end of the contact surface or contact edge of each element may be adjustable. For example, depending on the wire length, on the wire diameter, and on the size of the wire bundle, it is possible to adjust how far a wire must be extricated from the bundle by the removal wheel before the transport wheels can support the extricated wire during its movement. For example, the angle may be smaller for short and thin wires than for long and thick wires. Similarly, it may be smaller for small wire bundles than for large wire bundles. It is possible for the angle between the shelf plane and the upper end of the contact surface or alternatively contact edge to be individually adjustable for each element. For example, it may be advantageous to select a different angle for transport wheels or, alternatively, elements that are farther from the removal wheel than others, in particular, to select a smaller angle than for transport wheels or elements that are closer to the removal wheel.

Each of the prevention elements may be slidably mounted on a bracket, thereby allowing, in particular, the angle between the shelf plane and the upper end of the contact surface or contact edge of each element to be adjusted.

The guide of a removal and alignment device according to the disclosure may comprise at least one lower guide element and at least one upper guide element, wherein at least one of the upper guide elements and at least one of the lower guide elements may be associated with one another and form a gap into which the wires removed from the wire bundle can be conveyed by the removal wheel and the transport wheels. The width of the gap may be adjustable, for example to adapt the guide to wires of different thicknesses. To adjust the width of the gap, the at least one upper guide element may be mounted so as to be slidable.

### BRIEF DESCRIPTION OF THE DRAWINGS

Further features and advantages of embodiments of the disclosed device are described below with reference to the drawings providing schematic, simplified representations. In so doing, the same reference numbers are used for identical or similar parts and for parts with identical or similar functions.

FIG. 1a shows a perspective view of important parts of a device according to the disclosure, a wire bundle placed on a shelf of the device, and a wire removed from the wire bundle.

FIG. 1b shows the view from FIG. 1a without the wire bundle.

FIG. 2a shows a front view of important parts of the device, with the wire bundle and a wire removed from the wire bundle.

FIG. 2b shows the view from FIG. 2a without the wire bundle.

FIG. 3a shows a top view of important parts of the device, with the wire bundle and a wire removed from the wire bundle.

FIG. 3b shows the view from FIG. 3a without the wire bundle.

FIG. 4a shows a detail from FIG. 1a.

FIG. 4b shows a detail from FIG. 1b.

FIG. 5 shows a detail from a side view of a transport wheel.

FIG. 6 shows a side view of a prevention element used to block the wire from being entrapped in the entrainment notches of the transport wheels.

### DETAILED DESCRIPTION

It is not necessary that a device according to the disclosure comprises all of the features described below. It is also possible that a device according to the disclosure comprises only individual features of the embodiment described below.

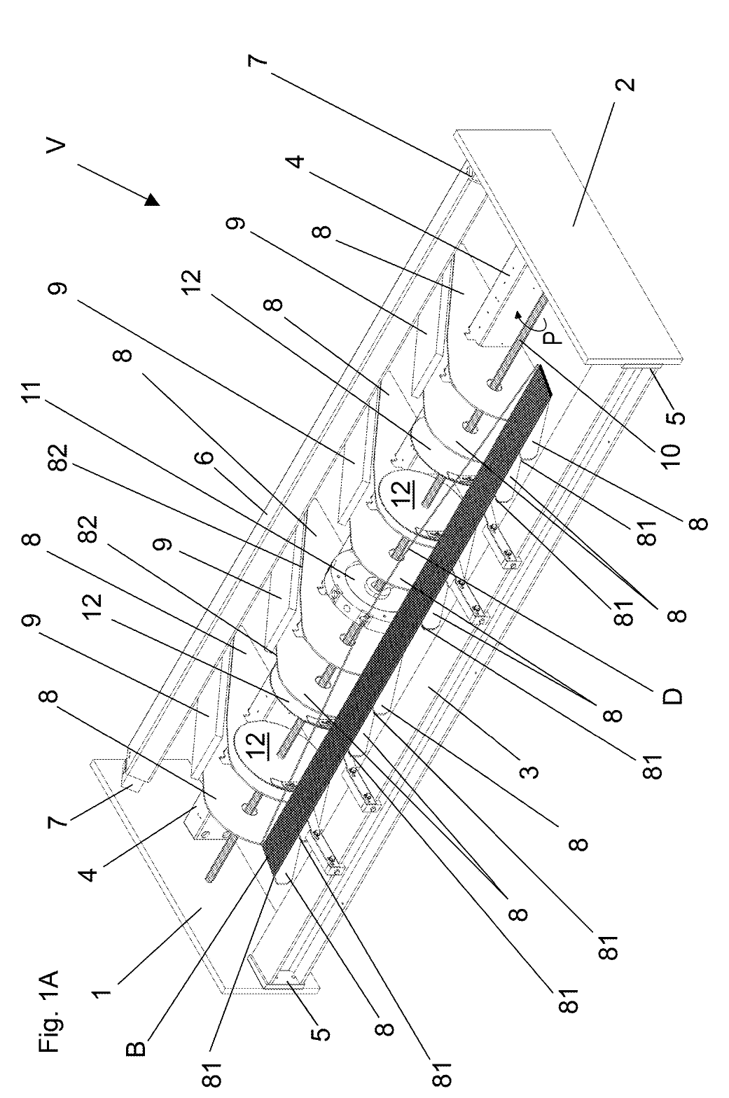

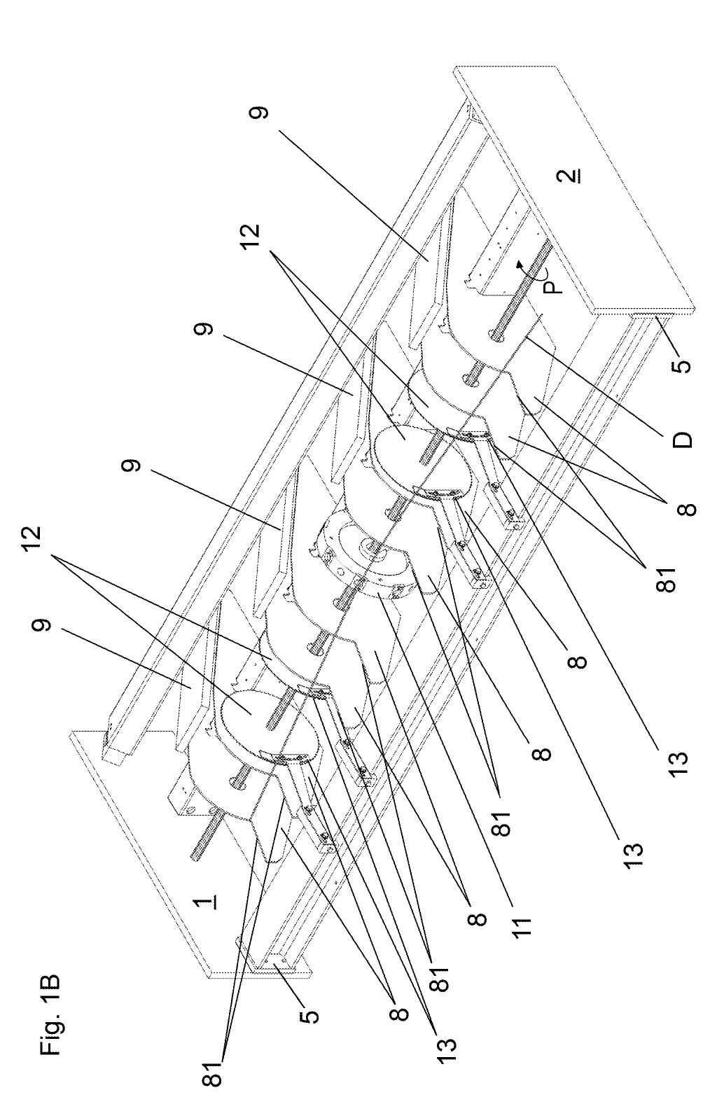

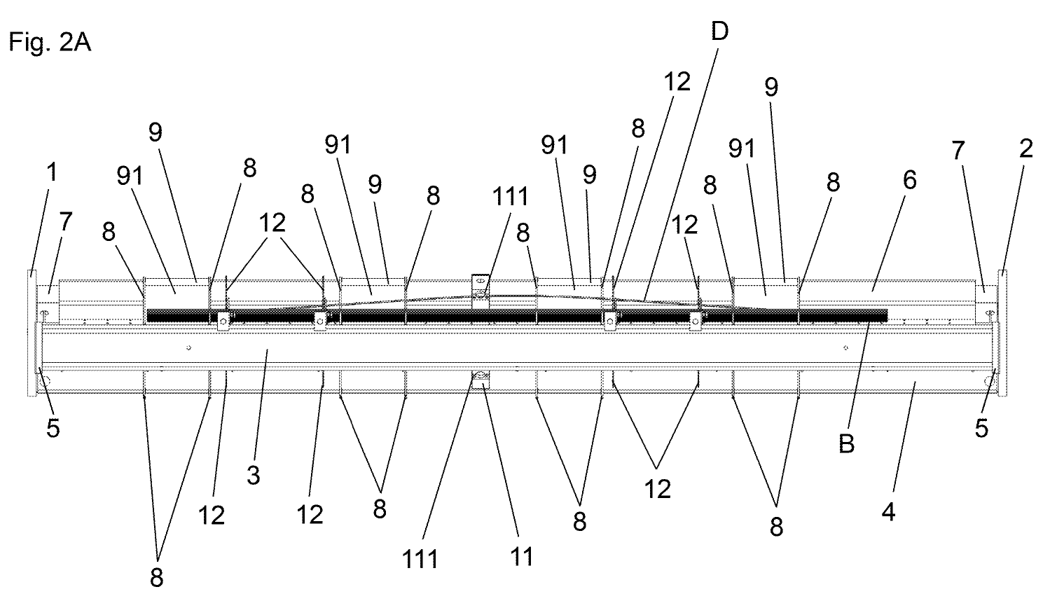

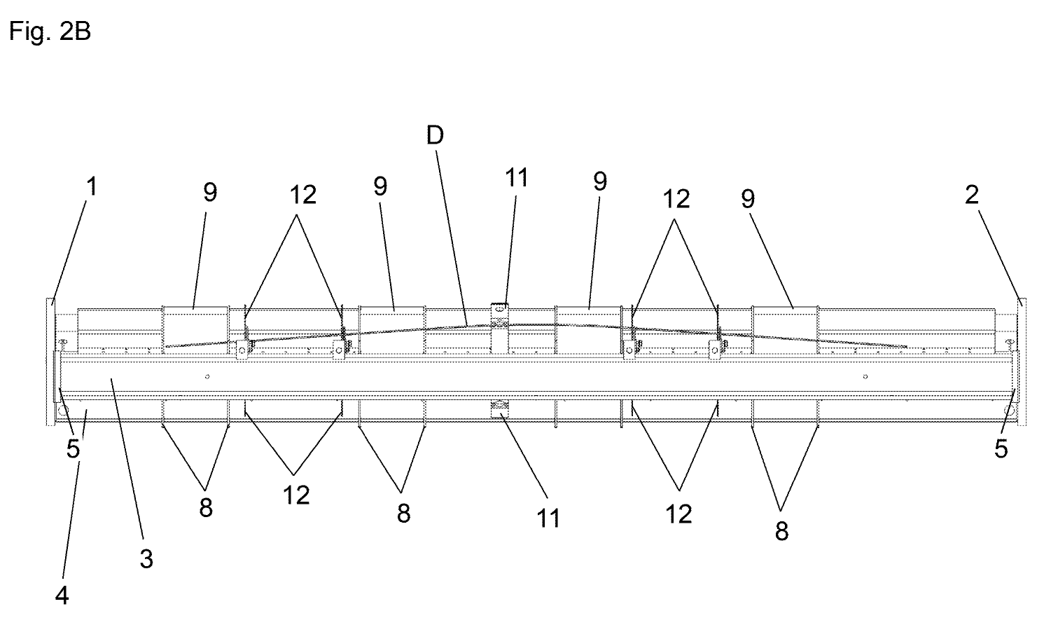

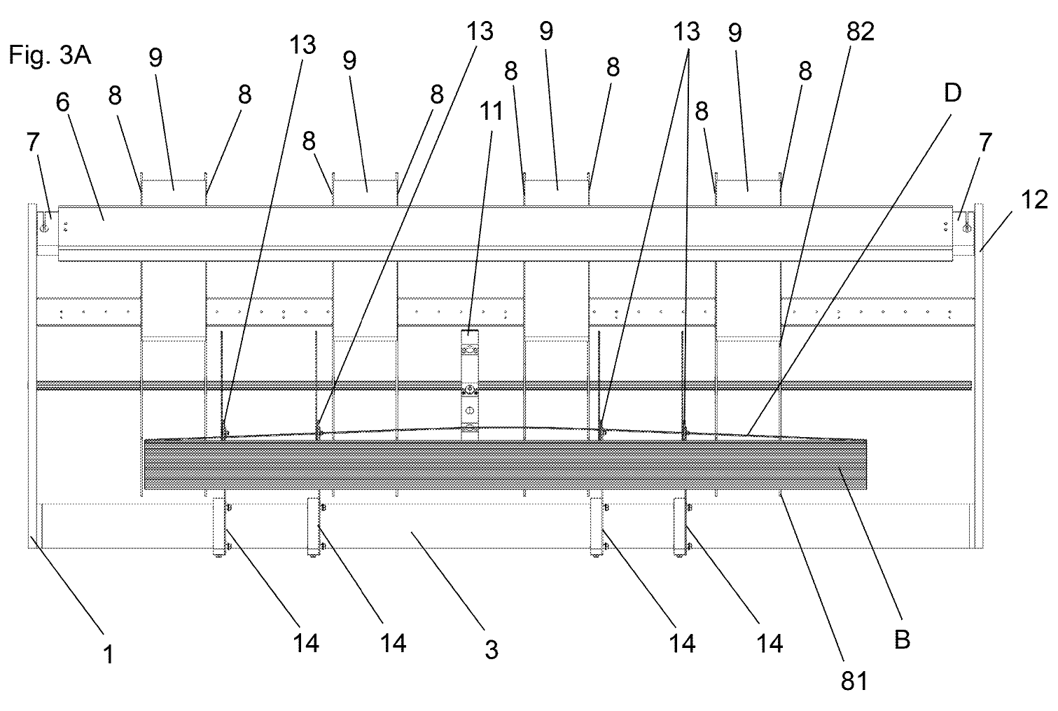

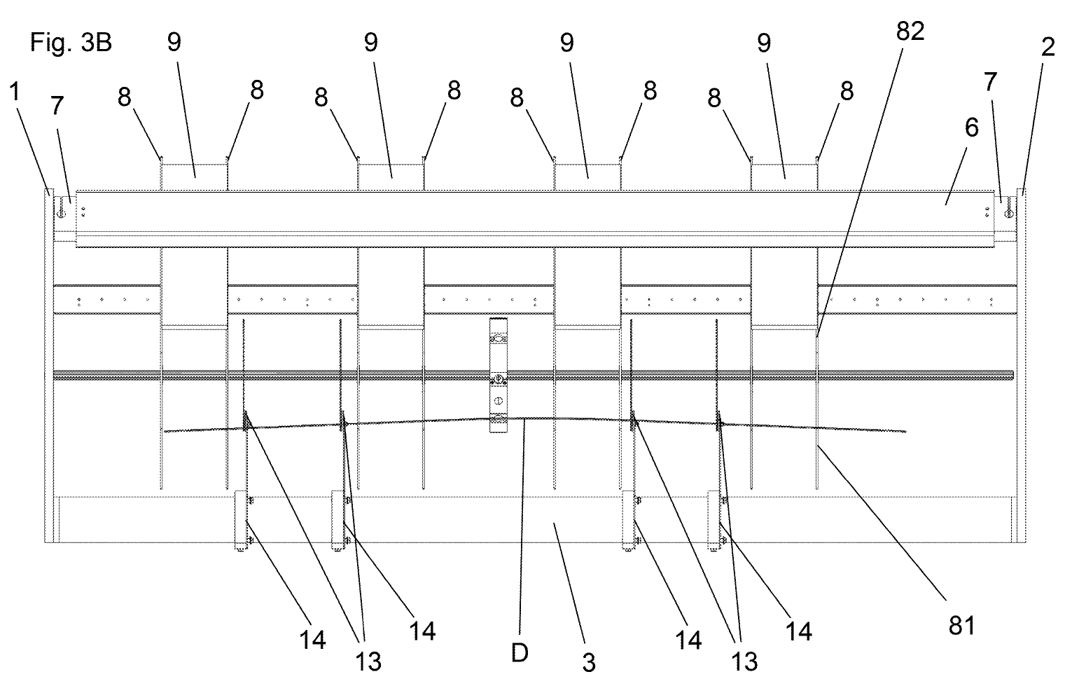

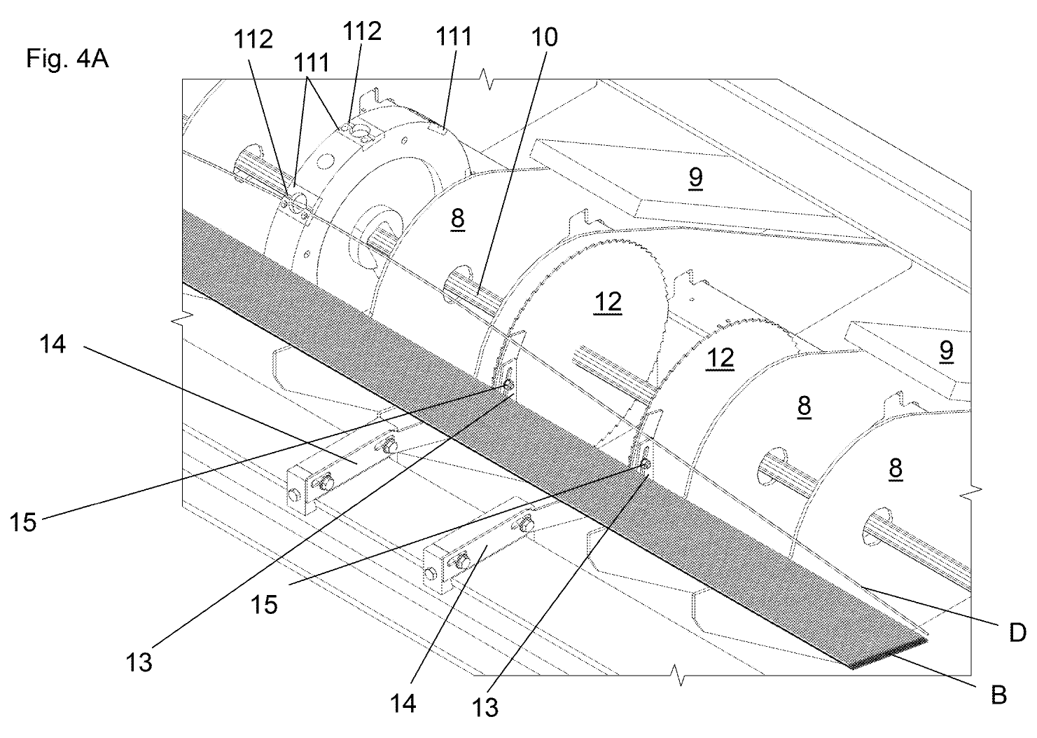

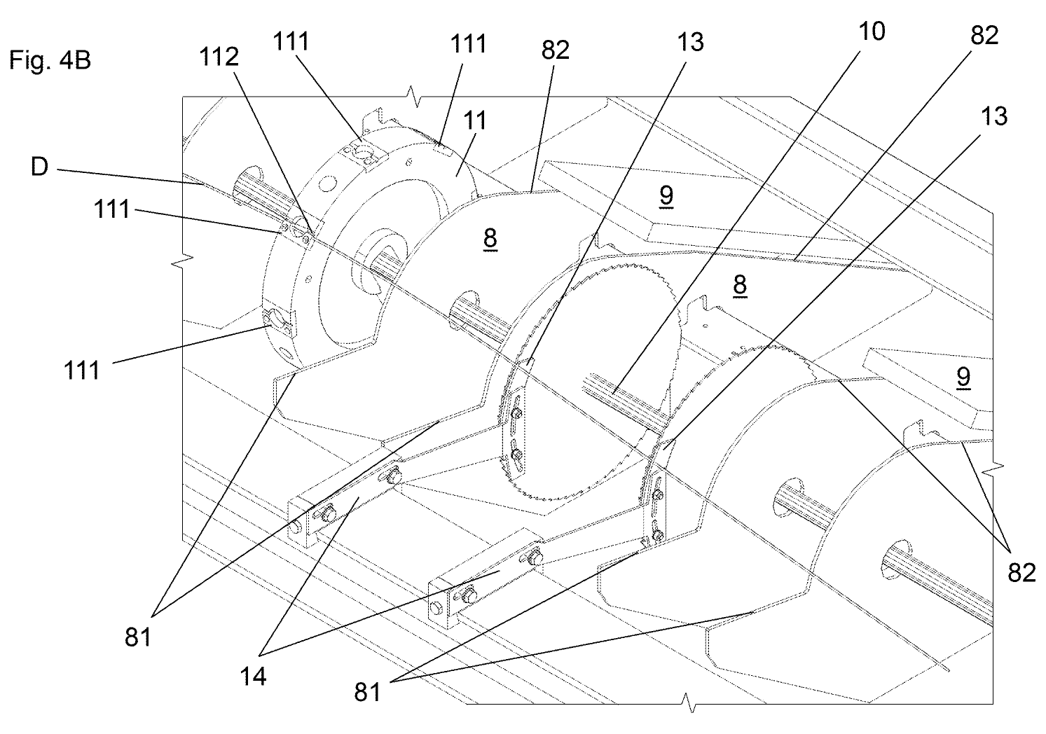

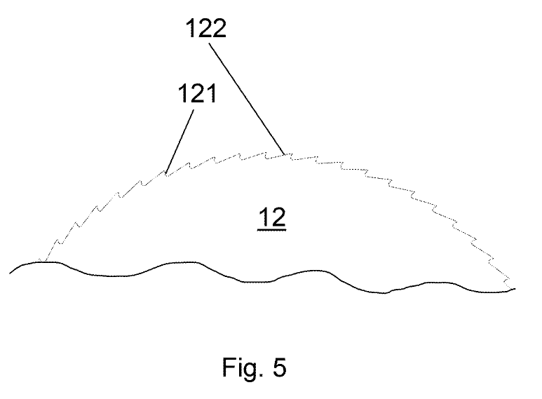

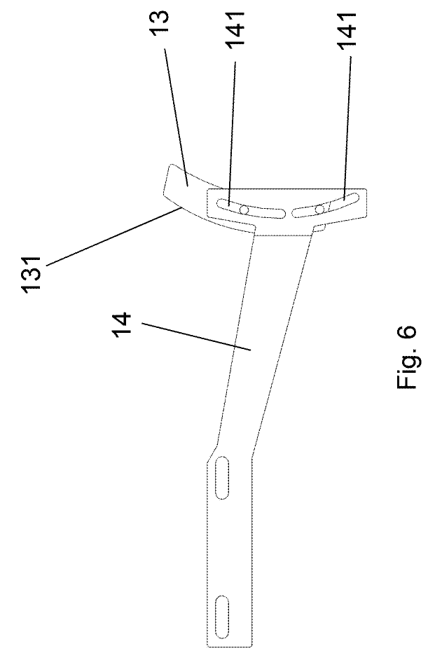

Referring to FIGS. 1a, 1b, 2a, 2b, 3a, 3b, 4a, 4b, 5 and 6, the device V according to the disclosure comprises a frame with two lateral frame parts 1, 2, a front frame part 3, a rear frame part 4, and front connecting parts 5. The front frame part 3 is inserted between the two side frame parts 1, 2 and connected to the side frame parts 1, 2 via the front connecting parts 5. The rear frame part 4 is inserted between the two side frame parts 1, 2 and connected to the side frame parts 1, 2.

A carrier 6 is also inserted between the two side frame parts 1, 2, which carrier is connected to the side frame parts 1, 2 via rear connecting parts 7.

Sheet metal pieces 8 are attached to the rear frame part 4. These sheet metal pieces 8 have holes that correspond to the cross-section of the rear frame section. The rear frame part 4 passes through these holes. The sheet metal pieces 8 rest on the rear frame part 4 and are thus connected to the frame of the device.

The sheet metal pieces 8 each have a first surface 81 on which a wire bundle B can be placed. Together, the first surfaces 81 form a shelf of the device V for the wire bundle B.

The sheet metal pieces 8 each also have a second surface 82. These form lower guide surfaces of a guide 82, 91 for wires removed from the wire bundle B. These wires are aligned by the guides.

The guide 82, 91 is completed by surfaces 91 of upper guide elements 9, which are attached to a bottom side of the carrier 6.

The device V further comprises a shaft 10, one end of which is mounted on one of the two lateral frame parts 1, 2 and which passes through the other lateral frame part 1, 2. An end of the shaft 10 passing through the other lateral frame part 1, 2 is connected to a drive of the device V (not shown). The drive rotates the shaft 10 in the direction of the arrow P.

A removal wheel 11 is mounted in a rotatably fixed manner on the shaft 10 approximately midway between the side frame members 1, 2. Two transport wheels 12 are mounted in a rotatably fixed manner on the shaft 10 on each side of the removal wheel 11, offset from the removal wheel 11 toward the side frame members 1, 2.

The removal wheel 11 comprises inserts 111 on its outer side, offset from one another at an angle of 45°. Each of these inserts 111 of the removal wheel 11 has a notch, referred to as an entrainment notch 112. These entrainment notches 112 are provided to remove and separate a wire D from the wire bundle B. The inserts 111 can be detached from the rest of the removal wheel 11 and replaced with other inserts whose entrainment notches 112 have different dimensions and/or a different shape and which are better suited for wires other than those shown in the figures.

The arrangement of the entrainment notches 112 at a 45° angle to one another makes it possible that the removal wheel 11 removes up to eight wires from the bundle B in a single rotation, separates them, and conveys them toward the guide by which the wires are aligned.

The transport wheels 12 comprise a border featuring a set of teeth in the form of saw teeth, wherein each saw tooth has a steep flank 121 and a flat flank 122. The steep flank 121 of one tooth and the flat flank 122 of an adjacent tooth form entrainment notches of the transport wheels. The steep flanks 121 of the saw teeth of this set of teeth are aligned such that a wire D, which has been extricated, by one of the entrainment notches 112 of the removal wheel 11, from the wire bundle B by the rotation of the removal wheel 11, is gripped and supported by the steep flank 121 of one of the teeth on the border of the transport wheel 12, such that the wire D is conveyed upward not only by the removal wheel 11 in the direction of rotation, but also by the transport wheels 12. The set of teeth of the transport wheels 12 is significantly narrower than the distribution of the eight entrainment notches 112 of the removal wheel 11. Thus, in substance, any of the transport wheels 12 can take a wire at virtually any time during its rotation and support it on its path from the shelf to the guide.

The device according to the disclosure further comprises prevention elements 13 used to block the wire from being entrapped in the entrainment notches of the transport wheels 12. These elements prevent that a wire from the wire bundle B is entrapped by one of the entrainment notches of a transport wheel 12 if it is not already entrapped by one of the entrainment notches 112 of the removal wheel 11. This is intended to ensure that only the wires that were previously removed from the wire bundle B by the removal wheel 11 are grasped and moved by the transport wheels 12. Each of the transport wheels 12 is assigned one of the elements 13, and vice versa.

These elements 12 comprise a circularly curved contact surface 131 arranged concentrically with respect to the shaft 10 and thus with respect to the transport wheels 13. The radius from the axis of rotation of the shaft 10 to this contact surface 131 is slightly greater than or equal to the radius from the axis of rotation to the tips of the teeth of the set of teeth of the associated transport wheel 12.

This contact surface 131 extends upward beyond the shelves formed by the surfaces 81 of the sheet metal pieces 8. The contact surface 131 covers the set of teeth of the associated transport wheel 12 from the shelf to the upper end of the contact surface 131. A wire lying on the shelf cannot for this reason be grasped by any of the transport wheels 12. A wire lying on the shelf can exclusively be grasped by the removal wheel 11. This removal wheel conveys the grasped portion of the wire D removed from the deposited bundle upward, as shown in the figures. In so doing, the sections of the wire D adjacent to the grasped section of the removed wire D are also progressively extricated from the bundle B and transported upward, starting from the center of the wire D and continuing toward the ends of the wire.

As a result, the wire D is gradually transported upward to such an extent that, starting from the center of the device or alternatively from the removal wheel 11, it is gradually lifted by the upper ends of the contact surfaces 131 of the prevention elements 13 used to block the wire D from being entrapped in the entrainment notches of the transport wheels 12. The wire D can then be entrained by one of the entrainment notches of the associated transport wheel 12. The transport wheel 12 can then support the wire D on its path to the guide, so that the wire D is not bent as sharply as it would be without support from the transport wheels 12. As soon as the wire has been lifted by the upper end of the contact surface of one of the elements 13, the wire D is sufficiently far from the shelf or alternatively from the wire bundle B that there is no longer any risk that the associated transport wheel 12 will grasp a wire other than the one grasped by the removal wheel 11.

Depending on the size of the wire bundle, the thickness of the wires to be separated, and/or the length of the wires, the height by which a removed wire must be conveyed upwards by the shelf or alternatively the wire bundle on the shelf so that a transport wheel 12 can grasp only that wire may be greater or smaller. It is therefore useful to be able to adjust the position of the ends of the contact surfaces 131 of the prevention elements 13 used to block the wire from being entrapped in the entrainment notches of the transport wheels 12. For this reason, these elements 13 are adjustable in the device V according to the disclosure shown. To this end, they are attached to holders 14, which in turn are attached to the front frame section 3. The holders 14 each have two circularly curved slotted holes 141, the circular curves of which are concentric with the axis of rotation of the shaft 10. A screw 15 is passed through each of these slotted holes 141 and screwed into the elements 13. The elements 13 are thereby attached to the bracket 14. If the screws 15 are slightly loosened, the elements 13 can be moved along the slotted holes to adjust the upper end of the contact surface 131.

As soon as the removed and thus separated wire has been rotated, starting from the shelf, by approximately 110° about the axis of rotation of shaft 10, the wire strikes the second surface 82 of the sheet metal pieces 8. These pieces extricate the wire D from the entrainment notches of the removal wheel 11 and the transport wheels 12. The wire then moves along the second surface 82 and rolls into the guide, whereby it is aligned and then stands ready at the end of the guide for further processing.

What is claimed is:

1. A device for removing wires from a wire bundle and for aligning wires, comprising:
a shelf to support the wire bundle;
a guide to align the wires removed from the wire bundle;
a rotatably mounted removal wheel to remove a wire from the wire bundle and to transfer the wire to the guide, the removal wheel comprising a notch for entraining the wire and into which the wire is entrapped during rotation of the removal wheel;
a drive to drive rotation of the removal wheel;
rotatable transport wheels arranged coaxially with the removal wheel and at a distance from the removal wheel in an axial direction, each of the transport wheels comprising a notch for entraining the wire that is entrapped in the notch of the removal wheel; and
prevention elements to block the wires from the wire bundle that are not entrapped in the notch of the removal wheel from being entrapped in notches of the transport wheels.

2. The device of claim 1, wherein the removal wheel is centrally arranged among the transport wheels along an axial direction.

3. The device of claim 1, wherein the drive is configured to drive the transport wheels.

4. The device of claim 1, further comprising a shaft on which the removal wheel and the transport wheels are arranged in a rotationally fixed manner.

5. The device of claim 1, wherein the transport wheels comprise a greater number of entrainment notches than the removal wheel.

6. The device of claim 1, wherein each of the transport wheels is associated with at least one of the prevention elements.

7. The device of claim 4, wherein the prevention elements extend beyond transport wheels in a radial direction from the shaft in a vicinity of the shelf.

8. The device of claim 7, wherein the prevention elements include a circularly curved contact surface or contact edge, wherein the contact surface or contact edge of each of the prevention elements lies on a circle around an axis of rotation of the transport wheels.

9. The device of claim 8, wherein an angle between a plane of the shelf and an upper end of the contact surface or contact edge of each of the prevention elements is adjustable.

10. The device of claim 9, wherein the angle between the plane of the shelf and the upper end of the contact surface or contact edge is individually adjustable for each of the prevention elements.

11. The device of claim 8, wherein each of the prevention elements is slidably mounted on a bracket such that an angle between a plane of the shelf and an upper end of the contact surface or contact edge of each of the prevention elements is adjustable.

12. The device of claim 1, wherein the guide comprises at least one lower guide element and at least one upper guide element, wherein at least one of the upper guide elements and at least one of the lower guide elements are associated with one another and form a gap into which wires removed from the wire bundle are conveyed by the removal wheel and the transport wheels.

13. The device of claim 12, wherein a height of the gap is adjustable.

14. The device of claim 13, wherein, to adjust the height of the gap, the at least one upper guide element is mounted so as to be slidable.

15. A method for removing wires from a wire bundle and for aligning removed wires with the device of claim 8, the method comprising:
rotating the removal wheel and the transport wheels;
entrapping an entrained wire from the wire bundle in the notch of the removal wheel,
moving the entrained wire along the contact surface or the contact edge of the prevention elements to an upper end of the prevention elements;
above the prevention elements, entrapping the entrained wire in the notches of the transport wheels;
transporting the entrained wire entrapped in the notches of the transport wheels to the guide; and
extricating the entrained wire from the notches of the removal wheel and the transport wheels as the entrained wire reaches the guide.
